(19) United States
(12) Patent Application Publication
(10) Pub. No.: US 2009/0189042 A1
(43) Pub. Date: Jul. 30, 2009

(54) MOUNTING APPARATUS FOR ELECTRONIC DEVICE

(75) Inventors: YUN-LUNG CHEN, Tu-Cheng (TW); Da-Long Sun, Shenzhen City (CN); Wan-Cheng Lin, Tu-Cheng (TW); Pei-Bin Luo, Shenzhen City (CN)

Correspondence Address: PCE INDUSTRY, INC.;ATT. Steven Reiss, 458 E. LAMBERT ROAD, FULLERTON, CA, 92835, US

(73) Assignees: HONG FU JIN PRECISION INDUSTRY (ShenZhen) CO., LTD, Shenzhen City (CN); HON HAI PRECISION INDUSTRY CO., LTD., Tu-Cheng (TW)

(21) Appl. No.: 12/107,776

(22) Filed: Apr. 23, 2008

(30) Foreign Application Priority Data
Jan. 24, 2008 (CN) 200820300138.3

(51) Int. Cl. A47B 96/06; H05K 5/00; G06F 1/16; H05K 7/14

(52) U.S. Cl. 248/309.1; 248/221.12; 312/223.2; 361/807; 361/679.33

(57) ABSTRACT

A mounting apparatus for an electronic device includes a mounting bracket for receiving the electronic device and a securing member pivotally attached to the mounting bracket. The mounting bracket includes a sidewall. The securing member includes a securing arm having an operating portion and a securing portion, and an elastic driving portion connected to the operating portion. A free end of the driving portion resiliently abuts against the sidewall to apply an elastic force onto the operating portion in a direction away from the sidewall and onto the securing portion in a direction toward the first sidewall. The securing portion extends through the sidewall of the mounting bracket to engaging with the electronic device.

### BACKGROUND

1. Field of the Invention

The present invention relates to mounting apparatuses, particularly to a mounting apparatus for an electronic device.

2. Description of Related Art

A typical personal computer comprises data storage devices such as a hard disk drive (HDD), a floppy disk drive, and a compact disc-read only memory (CD-ROM) drive. Conventionally, the data storage devices are attached to a chassis of a computer enclosure using screws. A tool such as a screwdriver is required to fasten the screws, and to unfasten the screws when removing the data storage devices. The operations are laborious and time-consuming. Furthermore, even careful operators may cause the tool to slip, or may drop screws. When this happens, other internal components of the computer are liable to be damaged.

Accordingly, what is needed is a mounting apparatus whereby fans can be more easily attached and removed from the electronic device enclosure

### SUMMARY

A mounting apparatus for an electronic device includes a mounting bracket for receiving the electronic device and a securing member pivotally attached to the mounting bracket. The mounting bracket includes a sidewall. The securing member includes a securing arm having an operating portion and a securing portion, and an elastic driving portion connected to the operating portion. A free end of the driving portion resiliently abuts against the sidewall to apply an elastic force onto the operating portion in a direction away from the sidewall and onto the securing portion in a direction toward the first sidewall. The securing portion extends through the sidewall of the mounting bracket to engaging with the electronic device.

Other advantages and novel features of the present invention will become more apparent from the following detailed description of preferred embodiment when taken in conjunction with the accompanying drawings, in which:

### BRIEF DESCRIPTION OF THE DRAWINGS

FIG. 1 is an isometric, exploded view of a mounting apparatus for an electronic device together with the electronic device, the mounting apparatus comprising a mounting bracket and a securing member;

FIG. 2 is an isometric, assembled view of the mounting apparatus;

FIG. 3 is an isometric, assembled view of the mounting apparatus and the electronic device, with the securing member disengaged from the electronic device; and

FIG. 4 is an isometric, assembled view of the mounting apparatus and the electronic device, with the securing member engaged with the electronic device.

### DETAILED DESCRIPTION OF THE EMBODIMENT

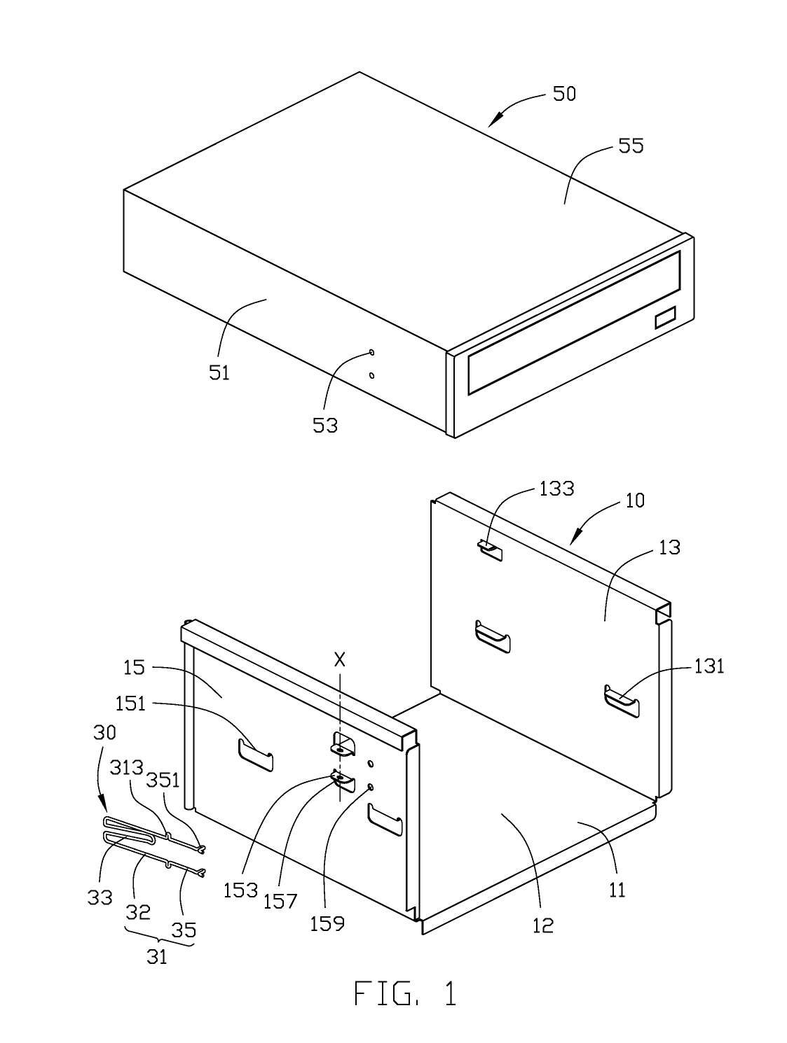

Referring to FIG. 1, a mounting apparatus for mounting an electronic device 20 includes a mounting bracket 10 and a securing member 30 pivotally attached thereto. The electronic device 20 defines two securing holes 53 at one of sidewalls 51 thereof.

The mounting bracket 10 includes a bottom wall 11 and first and second sidewalls 13, 15 perpendicularly extending from two opposite side edges of the bottom wall 11 respectively. The bottom wall 11 and the first and second sidewalls 13, 15 together define a receiving housing 12 for accommodating the electronic device 20. Two aligned supporting tabs 131 in parallel to the bottom wall 11 perpendicularly extend into the receiving housing 12 from the first sidewall 13, for supporting the electronic device 20. A blocking tab 133 extends into the receiving housing 12 above the two supporting tabs 131. A distance between the supporting tabs 131 and the blocking tab 133 is substantially equal to the thickness of the electronic device 20. Two supporting tabs 151 extend into the receiving housing 12 corresponding to the supporting tabs 131, for cooperatively supporting the electronic device 20 therebetween. Two opposite pivoting tabs 153 aligned in a direction perpendicular to the bottom wall 11 perpendicularly extend outward from the second sidewall 15. Each pivoting tab 153 defines a pivot hole 157 therein. The pivot holes 157 are aligned in a direction parallel to the second sidewall 15 of the mounting bracket 10, thereby defining a pivot axis “X” parallel to and spaced from the second sidewall 15 for the securing member 30 pivoting thereabout. Two securing holes 159 are defined in the first sidewall 15 adjacent to and respectively aligned with the pivoting tabs 153.

The securing member 30 is integrally formed with wire-shaped metal material and substantially M-shaped. The securing member 30 includes two thin, spaced, and substantially parallel securing arms 31 and a substantially U-shaped elastic driving portion 33 bent back from distal ends of the securing arms 31. The driving portion 33 is located between the securing arms 31, and a free end of the driving portion 33 is offset from the two securing arms 31 toward the second sidewall 15 of the mounting bracket 10 with an angle. Two oppositely extending pivot posts 313 corresponding to the pivot holes 157 in the mounting bracket 10 respectively protrude from middle portions of the securing arms 31, thereby dividing each securing arm 31 into an operating portion 32 connected to the driving portion 33 and a securing portion 35 engaging with the second sidewall 15 of the mounting bracket 10. Two securing protrusions 351 corresponding to the securing holes 159 in the second sidewall 15 respectively extend toward the second sidewall 15 from distal ends of the securing portions 35 of the securing member 30.

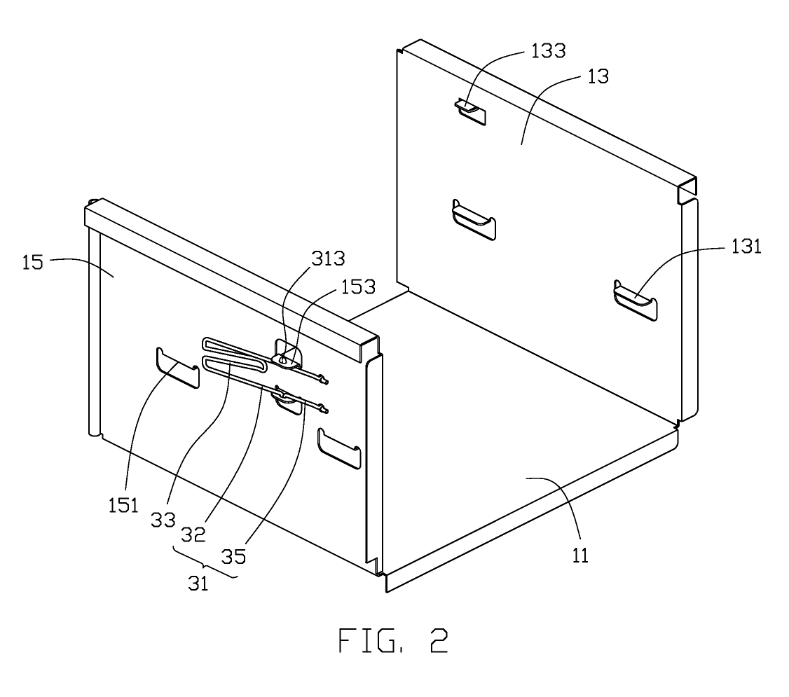

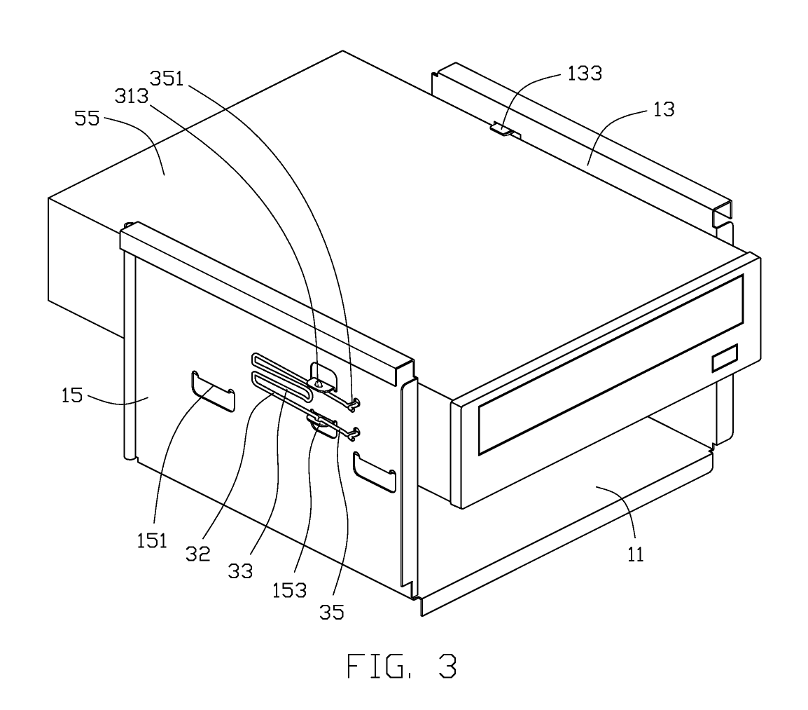

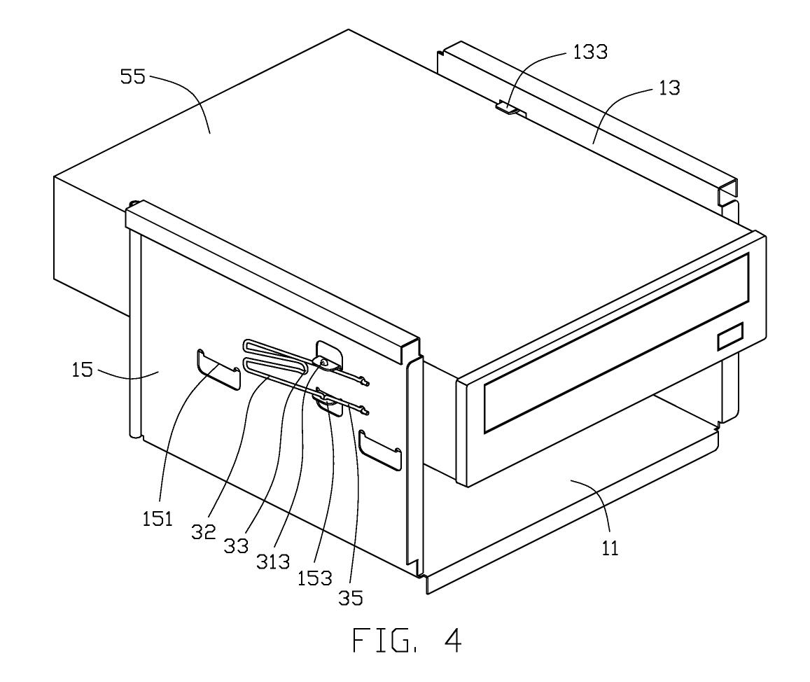

Referring also to FIGS. 2-4, in assembly, the two securing arms 31of the securing member 30 are pressed toward each other. The pivot posts 313 are respectively aligned with the corresponding pivot holes 157 in the pivot tabs 153 of the mounting bracket 10. Then, the securing arms 31 are released and rebound back to a natural state, and the pivot posts 313 extend through the pivot holes 157. Thus, the securing member 30 is attached to the second sidewall 15 of the mounting bracket 10 and is capable of pivoting about the pivot axis “X”. In an initial state, the free end of the driving portion 33 offset from the securing members 31 abuts against the second sidewall 15 of the mounting bracket 10, to provide an elastic force for driving the operating portions 32 of the securing arms 31 away from the second sidewall 15, and driving the securing portions 35 of the securing arms 31 to the second sidewall 15. The securing protrusions 351 are urged to extend through the corresponding securing holes 159 in the second sidewall 15. In assembly of the electronic device, the distal ends of the operating portions 32 of the securing arms 31 are pushed toward the second sidewall 15. The driving portion 33 is distorted close to the securing arms 31. The securing arms 31 pivot in the pivot holes 157 about the pivot posts 313 to drive the securing portions 35 of the securing arms 31 move away from the second sidewall 15 of the mounting bracket 10. The securing protrusions 351 of the securing portions 35 are disengaged from the corresponding securing holes 159 in the second sidewall 15. Then, the electronic device 50 is disposed in the receiving housing 12 and pushed along the supporting tabs 131 and 151 on the first and second sidewalls 13 and 15. The sidewalls 51 of the electronic device 50 respectively abut against the first and second sidewalls 13 and 15. The blocking tab 133 abuts on a top wall 55 of the electronic device 50 to limiting a movement perpendicular to the bottom wall 11 of the mounting bracket 10. When the securing holes 53 in the electronic devices 50 are aligned with the securing holes 159 in the second sidewall 15, the securing arms 31 are released. The driving portion 33 rebounds back and forces the securing arms 31 to pivot back to the initial state, thereby urging the securing protrusions 351 of the securing arms 31 to extend through the securing holes 159 and engage in the securing holes 53 in the electronic device 50. Thus, the electronic device 50 is secured to the mounting bracket 10.

In disassembly, the distal ends of the operating portions 32 of the securing arms 31 are pushed toward the second sidewall 15. The driving portion 33 is distorted close to the securing arms 31. The securing arms 31 pivot about the pivot posts 313 to drive the securing portion 35 of the securing arms 31 to be moved away from the second sidewall 15 of the mounting bracket 10. The securing protrusions 351 of the securing portions 35 are disengaged from the securing holes 53 in the electronic device 50. Thus, the electronic device 50 can be removed from the mounting bracket 10.

It is to be understood, however, that even though numerous characteristics and advantages of the present invention have been set forth in the foregoing description, together with details of the structure and function of the invention, the disclosure is illustrative only, and changes may be made in detail, especially in matters of shape, size, and arrangement of parts within the principles of the invention to the full extent indicated by the broad general meaning of the terms in which the appended claims are expressed.

What is claimed is:

1. A mounting apparatus for an electronic device, comprising:
a mounting bracket for receiving the electronic device comprising a sidewall; and
a securing member pivotally attached to the sidewall of the mounting bracket, the securing member comprising at least one securing arm having an operating portion and a securing portion, an elastic driving portion connected to the operating portion, a free end of the driving portion resiliently abutting against the sidewall to apply an elastic force onto the operating portion in a direction away from the sidewall and onto the securing portion in a direction toward the sidewall, the securing portion extending through the sidewall of the mounting bracket for engaging with the electronic device.

2. The mounting apparatus for an electronic device as described in claim 1, wherein the securing member comprises two substantially parallel securing arms, the elastic driving portion is connected between the two securing arms and offset therefrom toward the sidewall of the mounting bracket with an angle.

3. The mounting apparatus for an electronic device as described in claim 2, wherein two pivot tabs each defining a pivot hole therein perpendicularly extend from the sidewall of the mounting bracket, two oppositely extending pivot posts corresponding to the pivot holes respectively protrude from the two securing arms at joints of the operating portions and the securing portions.

4. The mounting apparatus for an electronic device as described in claim 3, wherein the two pivot holes in the pivot tabs are aligned in a direction parallel to the sidewall, thereby defining a pivot axis for the securing member pivot thereabout.

5. The mounting apparatus for an electronic device as described in claim 3, wherein two securing holes are defined in the sidewall of the mounting bracket adjacent to the pivot tabs, two securing protrusions corresponding to the securing holes respectively extend toward the sidewall from distal ends of the securing portion of the securing member.

6. The mounting apparatus for an electronic device as described in claim 1, wherein the mounting bracket comprises another sidewall opposite to said sidewall and a bottom wall connected between the two sidewalls, and the two sidewalls and the bottom wall together define a receiving housing for the electronic device, at least one supporting tab is perpendicularly extends in the receiving housing from each sidewall, for the electronic device being supported thereon.

7. The mounting apparatus for an electronic device as described in claim 6, wherein a blocking tab perpendicularly extends in the receiving housing from one of the sidewalls, for abutting on a top of the electronic device.

8. The mounting apparatus for an electronic device as described in claim 2, wherein the securing member has a M-shaped configuration.

9. The mounting apparatus for an electronic device as described in claim 8, wherein the securing member is integrally formed from a resilient wire.

10. A mounting apparatus for an electronic device, comprising:
a mounting bracket for receiving the electronic device comprising a sidewall, at least one pivot tab defining a pivot hole therein perpendicularly extending from the sidewall; and
a securing member comprising at least one securing arm and an elastic driving portion connected to one end of the at least one securing arm, a pivot post corresponding to the pivot hole of the mounting bracket protruding from the at least one securing arm, the pivot post and the corresponding pivot hole together define a pivot axis parallel to sidewall of the mounting bracket, a free end of the driving portion resiliently abutting against the first sidewall to provide an elastic force to drive the securing member to pivot about the pivot axis, and the other end of the securing member extending through the sidewall of the mounting bracket to engage with the electronic device.

11. The mounting apparatus for an electronic device as described in claim 10, wherein the securing member comprises two spaced securing arms, the elastic driving portion is connected between the two securing arms and offset therefrom toward the sidewall of the mounting bracket with an angle.

12. The mounting apparatus for an electronic device as described in claim 1, wherein the sidewall forms two pivot tabs defining pivot holes, two oppositely extending pivot posts corresponding to the pivot holes respectively protrude from a middle of the securing arms to divide each securing arm into an operating portions and a securing portion, the operating portions are connected to the driving portion.

13. The mounting apparatus for an electronic device as described in claim 12, wherein the two pivot holes in the pivot tabs are aligned in a direction parallel to the sidewall, thereby defining the pivot axis for the securing member pivot thereabout.

14. The mounting apparatus for an electronic device as described in claim 12, wherein two securing holes are defined in the sidewall of the mounting bracket adjacent to the pivot tabs, two securing protrusions corresponding to the securing holes respectively extend toward the sidewall from distal ends of the securing portion of the securing member.

15. The mounting apparatus for an electronic device as described in claim 10, wherein the mounting bracket comprises another sidewall opposite to said sidewall and a bottom wall connected between the two sidewalls, and the two sidewalls and the bottom wall together define a receiving housing for the electronic device, at least one supporting tab is perpendicularly extends in the receiving housing from each sidewall, for the electronic device being supported thereon.

16. The mounting apparatus for an electronic device as described in claim 15, wherein a blocking tab perpendicularly extends in the receiving housing from one of the sidewalls, for abutting on a top of the electronic device

17. The mounting apparatus for an electronic device as described in claim 1, wherein the securing member is M-shaped and integrally formed from wire-shaped material.

18. An apparatus comprising:
a disk drive having a sidewall and an engaging hole defined in the sidewall;
a mounting bracket having a first sidewall and a second sidewall, the disk drive sandwiched between the first and second sidewalls, the first sidewall having a through hole; and
a securing member mounted on an opposite side of the first sidewall to the disk drive, the securing member comprising a pivoted portion coupled to the first sidewall, a securing arm and an elastic driving portion, the securing arm and the elastic driving portion arranged at opposite sides of the pivoted portion, the securing arm having an engaging protrusion at a distal end thereof, the engaging protrusion extending through the through hole of the first sidewall and engaging in the engaging hole of the disk drive, the elastic driving portion resiliently abutting against the first sidewall, the elastic driving portion creating and applying an elastic force onto the engaging protrusion in a direction toward the first sidewall.
